(19) United States
(12) Patent Application Publication
(10) Pub. No.: US 2025/0202456 A1
(43) Pub. Date: Jun. 19, 2025

(54) ACOUSTIC WAVE FILTER

(71) Applicant: Murata Manufacturing Co., Ltd., Nagaokakyo-shi (JP)

(72) Inventor: Akira NOGUCHI, Nagaokakyo-shi (JP)

(21) Appl. No.: 18/976,398

(22) Filed: Dec. 11, 2024

(30) Foreign Application Priority Data
Dec. 19, 2023 (JP) 2023-214246

(51) Int. Cl. H03H 9/64; H03H 9/25

(52) U.S. Cl. CPC H03H 9/6483; H03H 9/25

(57) ABSTRACT

An acoustic wave filter includes input and output terminals and, one or more series arm resonators in a series arm path connecting the input and output terminals, parallel arm resonators connected between the series arm path and a ground, and an inductor connected to the input and output terminal and provided in series in the series arm path. A resonant frequency and an anti-resonant frequency of a parallel arm resonator connected closest to the inductor among the parallel arm resonators are outside a frequency range of the first band.

### CROSS REFERENCE TO RELATED APPLICATIONS

This application claims the benefit of priority to Japanese Patent Application No. 2023-214246 filed on Dec. 19, 2023. The entire contents of this application are hereby incorporated herein by reference.

### BACKGROUND OF THE INVENTION

### 1. Field of the Invention

The present invention relates to acoustic wave filters.

### 2. Description of the Related Art

International Publication No. WO2021/015187 discloses a ladder acoustic wave filter including a series arm resonator and a parallel arm resonator formed of an acoustic wave resonator. By adjusting an interdigital transducer (IDT) electrode structure, a resonant frequency and an anti-resonant frequency of the acoustic wave resonator are optimized to improve steepness in a pass band.

In the ladder acoustic wave filter, the anti-resonant frequency of the parallel arm resonator is generally positioned near the center of the pass band of the acoustic wave filter. In this case, however, the impedance in the anti-resonant frequency of the acoustic wave resonator is very high, and thus the impedance in the pass band of the parallel arm resonator is very high. In addition, when the size of the acoustic wave filter is reduced, the capacitance of the acoustic wave resonator decreases, and the impedance of the acoustic wave resonator increases. As a result, the impedance in the pass band of the acoustic wave filter becomes higher than a reference impedance, and there is a problem in that reduction in loss cannot be ensured.

### SUMMARY OF THE INVENTION

Accordingly, example embodiments of the present invention provide acoustic wave filters that are each reduced in loss and size.

According to an example embodiment of the present invention, an acoustic wave filter includes a pass band including a first band, the acoustic wave filter including a first input and output terminal and a second input and output terminal, one or more series arm resonators in a series arm path connecting the first input and output terminal and the second input and output terminal, a plurality of parallel arm resonators connected between the series arm path and a ground, and an inductor connected to the first input and output terminal and provided in series in the series arm path, in which a resonant frequency and an anti-resonant frequency of a first parallel arm resonator connected closest to the inductor among the plurality of parallel arm resonators are positioned outside a frequency range of the first band. In addition, according to an example embodiment of the present invention, an acoustic wave filter that includes a pass band including a first band, the acoustic wave filter including a first input and output terminal and a second input and output terminal, one or more series arm resonators in a series arm path connecting the first input and output terminal and the second input and output terminal, a plurality of parallel arm resonators connected between the series arm path and a ground, and an inductor provided in series between the first input and output terminal and the one or more series arm resonators, in which each of the plurality of parallel arm resonators includes an IDT electrode, and when a frequency range of the first band is represented by BWS, a center frequency of the first band is represented by f₀S, an electrode finger pitch of the IDT electrode of a first parallel arm resonator connected closest to the inductor among the plurality of parallel arm resonators is represented by P1, and an average value of electrode finger pitches of the IDT electrodes of the plurality of parallel arm resonators excluding the first parallel arm resonator is represented by P_{PA}, P1≥P_{PA}×{1+ (BWS/f₀S)/2} is satisfied.

In addition, according to an example embodiment of the present invention, an acoustic wave filter includes a pass band including a first band, the acoustic wave filter including a first input and output terminal and a second input and output terminal, one or more series arm resonators in a series arm path connecting the first input and output terminal and the second input and output terminal, a plurality of parallel arm resonators connected between the series arm path and a ground, and an inductor in series between the first input and output terminal and the one or more series arm resonators, in which each of the one or more series arm resonators and the plurality of parallel arm resonators includes an IDT electrode, and when a frequency range of the first band is represented by BWS, a center frequency of the first band is represented by f₀S, an electrode finger pitch of the IDT electrode of a first parallel arm resonator connected closest to the inductor among the plurality of parallel arm resonators is represented by P1, and an average value of electrode finger pitches of the IDT electrodes of the one or more series arm resonators is represented by P_{SA}, P1≤P_{SA}×{1−(BWS/f₀S)/2} is satisfied.

According to example embodiments of the present invention, acoustic wave filters that are each reduced in loss and size are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of an acoustic wave filter according to an example embodiment of the present invention.

FIG. 2A is a plan view and a cross-sectional view schematically illustrating a first example of an acoustic wave resonator of an acoustic wave filter according to an example embodiment of the present invention.

FIG. 2B is a cross-sectional view schematically illustrating a second example of an acoustic wave resonator of an acoustic wave filter according to an example embodiment of the present invention.

FIG. 2C is a cross-sectional view schematically illustrating a third example of an acoustic wave resonator of an acoustic wave filter according to an example embodiment of the present invention.

FIGS. 3A and 3B are graphs illustrating bandpass characteristics of an acoustic wave filter according to an example embodiment of the present invention and impedance characteristics of a first parallel arm resonator.

FIGS. 4A and 4B are graphs illustrating bandpass characteristics of an acoustic filter wave according to Comparative Example and impedance characteristics of a first parallel arm resonator.

FIG. 5 is a Smith chart illustrating an impedance of a pass band of an acoustic wave filter according to an example embodiment of the present invention.

FIG. 6 is a diagram illustrating a relationship between a first band of an acoustic wave filter according to an example embodiment of the present invention and an anti-resonant frequency of a parallel arm resonator.

FIG. 7 is a graph illustrating bandpass characteristics of an acoustic wave filter according to an example embodiment of the present invention when the first parallel arm resonator of the acoustic wave filter is an acoustic wave resonator and when the first parallel arm resonator is a capacitive element.

FIG. 8 is a diagram illustrating a relationship between a first band of an acoustic wave filter according to a modified example of an example embodiment of the present invention and resonant frequencies of a first parallel arm resonator and series arm resonators.

FIG. 9 is a circuit configuration diagram illustrating a multiplexer according to an example embodiment of the present invention.

### DETAILED DESCRIPTION OF THE EXAMPLE EMBODIMENTS

Hereinafter, example embodiments of the present disclosure will be described in detail with reference to the drawings. All of the example embodiments described below describe comprehensive or specific examples. For example, numerical values, shapes, materials, components, or dispositions and connection forms of the components which are described in the following example embodiments are merely examples, and are not intended to limit the present invention. In the components of the following example embodiments, components which are not described in an independent claim will be described as optional components. In addition, sizes or size ratios of the components illustrated in drawings are not necessarily exact.

Each drawing is a schematic view in which emphasis, omission, or ratio adjustment is made as appropriate to represent example embodiments of the present invention, and is not necessarily illustrated strictly. In some cases, a shape, a positional relationship, and a ratio may be different from actual ones. In the drawings, the same or substantially same configurations are represented by the same reference numerals, and repeated description thereof will not be provided or will be simplified in some cases.

In the circuit configuration in the present disclosure, “being connected” represents not only a case of being directly connected through a connection terminal and/or a wire conductor but also a case of being electrically connected through a matching element or a switch circuit. “Being connected between A and B” represents being connected to both A and B between A and B.

In addition, in a circuit element arrangement in the present disclosure, “a circuit element A being disposed in series in a path B” represents that both of a signal input terminal and a signal output terminal of the circuit element A are connected between two wires defining at least a portion of the path B. At least one of the two wires may be, for example, an electrode or a terminal.

In addition, a term representing a relationship between elements such as “parallel” and “perpendicular”, a term representing a shape of an element such as “rectangular”, and a numerical range represent not only strict meanings but also a substantially equivalent range, for example, a range including an error of approximately several percent.

In addition, in the following example embodiments, a pass band of a filter is defined as a frequency band between two frequencies which are about 3 dB higher than a minimum value of an insertion loss inside the pass band.

In addition, in the example embodiments of the present invention, a resonant band width represents a frequency difference between an anti-resonant frequency and a resonant frequency of an acoustic wave resonator.

In addition, in the present disclosure, a first band represents at least one of an uplink operating band and a downlink operating band of a frequency band defined in advance by a standardization group or the like (for example, 3GPP (registered trademark) and the Institute of Electrical and Electronics Engineers (IEEE)) for a communication system constructed by using a Radio Access Technology (RAT). In an example embodiment, as the communication system, for example, a long term evolution (LTE) system, a 5th generation (5G)-new radio (NR) system, a wireless local area network (WLAN) system, and the like can be used, but the present invention is not limited thereto.

In addition, an uplink operating band of a frequency band represents a frequency range designated for uplink in the frequency band. In addition, a downlink operating band of a frequency band represents a frequency range designated for downlink in the frequency band.

In addition, the first band may include a plurality of the frequency bands. For example, the first band may include a downlink operating band of a band B13 for LTE or a band n13 for 5G-NR and a downlink operating band of a band B14 for LTE or a band n14 for 5G-NR.

### EXAMPLE EMBODIMENT

### 1. Circuit Configuration of Acoustic Wave Filter 10

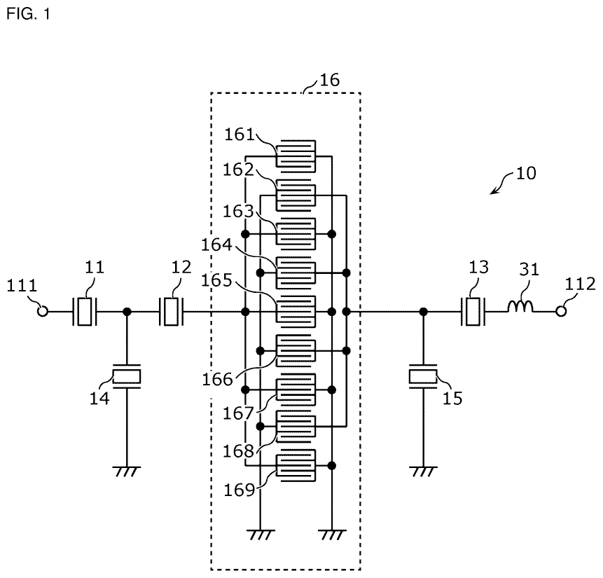

FIG. 1 is a circuit configuration diagram of an acoustic wave filter 10 according to an example embodiment of the present invention. As illustrated in FIG. 1, the acoustic wave filter 10 includes input and output terminals 111 and 112, series arm resonators 11, 12, and 13, parallel arm resonators 14 and 15, a longitudinally coupled resonator 16, and an inductor 31.

The series arm resonators 11 to 13 are one or more series arm resonators disposed in a series arm path connecting the input and output terminal 112 (first input and output terminal) and the input and output terminal 111 (second input and output terminal). Each of the series arm resonators 11 to 13 is an acoustic wave resonator, and the input and output terminal 111 is connected first to the series arm resonators 11, 12, and 13 in this order.

The parallel arm resonators 14 and 15 are a plurality of parallel arm resonators connected between the series arm path and a ground. Each of the parallel arm resonators 14 and 15 is an acoustic wave resonator. The parallel arm resonator 14 is connected between a connection point of the series arm resonators 11 and 12 and the ground. The parallel arm resonator 15 is connected between a connection point of the longitudinally coupled resonator 16 and the series arm resonator 13 and the ground. The parallel arm resonator 15 is an example of a first parallel arm resonator, and is connected closest to the inductor 31 among the parallel arm resonators 14 and 15.

The inductor 31 is connected to the input and output terminal 112 (first input and output terminal) and is disposed in series to the above-described series arm path. Specifically, one end of the inductor 31 is connected to the input and output terminal 112, and another end of the inductor 31 is connected to the series arm resonator 13.

The longitudinally coupled resonator 16 includes acoustic wave resonators 161, 162, 163, 164, 165, 166, 167, 168, and 169, one end is connected to the input and output terminal 111 through the series arm resonators 11 and 12, and another end is connected to the input and output terminal 112 through the series arm resonator 13 and the inductor 31.

Each of the acoustic wave resonators 161 to 169 includes an IDT electrode disposed on a substrate having piezoelectricity. The IDT electrode of the acoustic wave resonators 161 to 169 includes two comb-shaped electrodes facing each other. One comb-shaped electrode of each of the acoustic wave resonators 161, 163, 165, 167, and 169 is connected to the input and output terminal 111 through the series arm resonators 11 and 12, and another comb-shaped electrode of each of the acoustic wave resonators 161, 163, 165, 167, and 169 is connected to the ground. One comb-shaped electrode of each of the acoustic wave resonators 162, 164, 166, and 168 is connected to the input and output terminal 112 through the series arm resonator 13 and the inductor 31, and another comb-shaped electrode of each of the acoustic wave resonators 162, 164, 166, and 168 is connected to the ground. The acoustic wave resonators 161 to 169 are disposed along an acoustic wave propagation direction in order of the acoustic wave resonators 161, 162, 163, 164, 165, 166, 167, 168, and 169.

In the above-described connection configuration, the acoustic wave filter 10 defines a ladder band pass filter including the longitudinally coupled resonator and includes a pass band including a first band.

The first band may include, for example, a plurality of bands standardized by 3GPP (registered trademark). The first band is a frequency range (for example, about 746 MHz to about 768 MHZ) including a downlink operating band (for example, about 746 MHz to about 756 MHz) of a band B13 for LTE or a band n13 for 5G-NR and a downlink operating band (for example, about 758 MHz to about 768 MHz) of a band B14 for LTE or a band n14 for 5G-NR.

The acoustic wave filter 10 according to the present example embodiment may include at least one or more series arm resonators (any one of the series arm resonators 11 to 13), and two or more parallel arm resonators (parallel arm resonators 14 and 15) including the parallel arm resonator 15, and the inductor 31. In addition, the acoustic wave filter 10 according to the present example embodiment may include, for example, the longitudinally coupled resonator in addition to the series arm resonators and the parallel arm resonators forming the ladder filter.

### 2. Structure of Acoustic Wave Resonator

Next, a structure of the acoustic wave resonators defining the acoustic wave filter 10 will be described as an example.

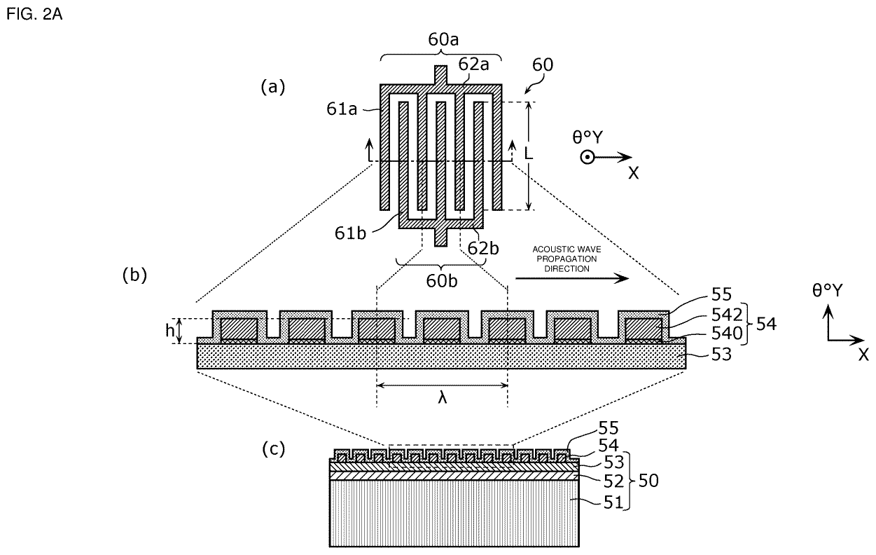

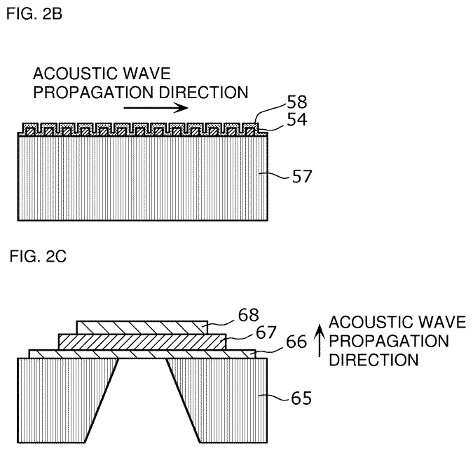

FIG. 2A is a plan view and a cross-sectional view schematically illustrating a first example of an acoustic wave resonator defining the acoustic wave filter 10 according to the present example embodiment. In FIG. 2A, a basic structure of each of the plurality of acoustic wave resonators of the acoustic wave filter 10 is illustrated as an example. An acoustic wave resonator 60 illustrated in FIG. 2A is an example for describing a typical structure of the surface acoustic wave resonator defining the acoustic wave filter 10, and the number and length of electrode fingers defining the electrode are not limited thereto.

The acoustic wave resonator 60 includes a piezoelectric substrate 50 and comb-shaped electrodes 60a and 60b.

As illustrated in (a) of FIG. 2A, the pair of comb-shaped electrodes 60a and 60b facing each other are provided on the piezoelectric substrate 50. The comb-shaped electrode 60a includes a plurality of electrode fingers 61a parallel or substantially parallel to each other and a busbar electrode 62a that connects the plurality of electrode fingers 61a to each other. The comb-shaped electrode 60b includes a plurality of electrode fingers 61b parallel or substantially parallel to each other and a busbar electrode 62b that connects the plurality of electrode fingers 61b to each other. The plurality of electrode fingers 61a and 61b are arranged along a direction orthogonal or substantially orthogonal to the acoustic wave propagation direction (X-axis direction).

In addition, as illustrated in (b) of FIG. 2A, an IDT electrode 54 including the plurality of electrode fingers 61a and 61b and the busbar electrodes 62a and 62b has a multilayer structure including a close contact layer 540 and a main electrode layer 542.

The close contact layer 540 is a layer for improving close contact between the piezoelectric substrate 50 and the main electrode layer 542, and as a material thereof, for example, Ti is used. As a material of the main electrode layer 542, for example, Al including about 1% of Cu is used. A protective layer 55 covers the comb-shaped electrodes 60a and 60b. The protective layer 55 is a layer to protect the main electrode layer 542 from an outside environment, to adjust frequency-temperature characteristics, and to improve humidity resistance, and for example, is a dielectric film including silicon dioxide as the main component.

Materials of the close contact layer 540, the main electrode layer 542, and the protective layer 55 are not limited to the above-described materials. Furthermore, the IDT electrode 54 does not need to have the above-described multilayer structure. The IDT electrode 54 may be made of, for example, a metal or an alloy such as Ti, Al, Cu, Pt, Au, Ag, or Pd, and may include a plurality of multilayer bodies made of the above-described metal or alloy. In addition, the protective layer 55 does not need to be provided.

Next, the multilayer structure of the piezoelectric substrate 50 will be described.

As illustrated in (c) of FIG. 2A, the piezoelectric substrate 50 includes a high acoustic velocity support substrate 51, a low acoustic velocity film 52, and a piezoelectric film 53, and in which the high acoustic velocity support substrate 51, the low acoustic velocity film 52, and the piezoelectric film 53 are stacked in this order.

For example, the piezoelectric film 53 is made of a θ° Y-cut X propagation LiTaO₃ piezoelectric single crystal or a piezoelectric ceramic (a single crystal or a ceramic through which the surface acoustic wave propagates in an X-axis direction, which is lithium tantalate single crystal or a ceramic cut along a plane in which the X-axis is set as a central axis, and an axis rotated by θ° from the Y-axis is set as a normal line). A material and a cut-angle θ of the piezoelectric single crystal used as the piezoelectric film 53 are appropriately selected depending on required specifications of each filter.

The high acoustic velocity support substrate 51 supports the low acoustic velocity film 52, the piezoelectric film 53, and the IDT electrode 54. Further, the high acoustic velocity support substrate 51 is a substrate in which the acoustic velocity of a bulk wave in the high acoustic velocity support substrate 51 is higher than the acoustic velocity of the acoustic wave of a surface acoustic wave or a boundary acoustic wave propagating through the piezoelectric film 53, and defines and functions to prevent the surface acoustic wave from leaking down from the high acoustic velocity support substrate 51 by confining the surface acoustic wave in a portion at which the piezoelectric film 53 and the low acoustic velocity film 52 are stacked. As a material of the high acoustic velocity support substrate 51, for example, a piezoelectric body such as aluminum nitride, lithium tantalate, lithium niobate, or crystal, a ceramic such as alumina, sapphire, magnesia, silicon nitride, silicon carbide, zirconia, cordierite, mullite, steatite, forsterite, spinel, or sialon, a dielectric such as aluminum oxide, silicon oxynitride, diamond-like carbon (DLC), and diamond, or a semiconductor such as silicon, or a material including the above-described materials as the main components can be used. The above-described spinel includes an aluminum compound including one or more of Mg, Fe, Zn, and Mn, or oxygen. Examples of the above-described spinel can include MgAl₂O₄, FeAl₂O₄, ZnAl₂O₄, and MnAl₂O₄.

The low acoustic velocity film 52 is a film in which the acoustic velocity of the bulk wave in the low acoustic velocity film 52 is lower than that of the bulk wave propagating through the piezoelectric film 53, and is disposed between the piezoelectric film 53 and the high acoustic velocity support substrate 51. This structure and a property that energy of an acoustic wave essentially concentrates on a medium having a low acoustic velocity suppress leakage of surface acoustic wave energy to the outside of the piezoelectric film 53. As a material of the low acoustic velocity film 52, for example, a dielectric such as a compound obtained by adding fluorine, carbon, or boron to glass, silicon oxide, silicon oxynitride, lithium oxide, tantalum oxide, or silicon oxide, or a material including the above-described materials as the main component can be used.

According to the above-described multilayer structure of the piezoelectric substrate 50, a Q value in a resonant frequency and an anti-resonant frequency can be significantly increased, compared to a structure in the related art in which the piezoelectric substrate is used as a single layer. That is, since an acoustic wave resonator having a high Q value can be configured, a filter having a small insertion loss can be configured by using the acoustic wave resonator.

The high acoustic velocity support substrate 51 may have a structure in which a support substrate and a high acoustic velocity film where the acoustic velocity of the bulk wave propagating through the piezoelectric film 53 is higher than that of the acoustic wave such as the surface acoustic wave or the boundary acoustic wave propagating through the piezoelectric film 53 are stacked. In this case, as a material of the high acoustic velocity film, the same material as the material of the high acoustic velocity support substrate 51 can be used. As a material of the support substrate, for example, a piezoelectric body such as aluminum nitride, lithium tantalate, lithium niobate, or crystal, ceramic such as alumina, sapphire, magnesia, silicon nitride, silicon carbide, zirconia, cordierite, mullite, steatite, or forsterite, a dielectric such as diamond or glass, a semiconductor such as silicon or gallium nitride, or a resin, or a material including the above-described material as the main components can be used.

In the present specification, the “main component of the material” refers to a component in which an occupancy in the material exceeds 50% by weight. The above-described main component may exist in any one state of single crystal, polycrystal, and amorphous, or in a mixed state thereof.

FIG. 2B is a cross-sectional view schematically illustrating a second example of an acoustic wave resonator of the acoustic wave filter 10 according to the present example embodiment. In the acoustic wave resonator 60 illustrated in FIG. 2A, the example in which the IDT electrode 54 is provided on the piezoelectric substrate 50 including the piezoelectric film 53 has been described. However, as illustrated in FIG. 2B, the substrate on which the IDT electrode 54 is provided may be a piezoelectric single crystal substrate 57 including a single piezoelectric layer.

For example, the piezoelectric single crystal substrate 57 includes a piezoelectric single crystal of LiNbO₃. The acoustic wave resonator according to this example includes the piezoelectric single crystal substrate 57 of LiNbO₃, the IDT electrode 54, and a protective layer 58 formed on the piezoelectric single crystal substrate 57 and on the IDT electrode 54.

The multilayer structure, the material, the cut-angle, and the thickness of the piezoelectric film 53 and the piezoelectric single crystal substrate 57 described above may be appropriately changed depending on required bandpass characteristics and the like of the acoustic wave filter device. An acoustic wave resonator using a LiTaO₃ piezoelectric substrate or the like having another cut-angle other than the above-described cut-angle can achieve the same or substantially the same advantageous effect as that of the acoustic wave resonator 60 using the piezoelectric film 53 described above.

In addition, the substrate on which the IDT electrode 54 is provided may have a structure in which a support substrate, an energy confinement layer, and a piezoelectric film are stacked in this order. The IDT electrode 54 is provided on the piezoelectric film. As the piezoelectric film, for example, a LiTaO₃ piezoelectric single crystal or a piezoelectric ceramic is used. The support substrate supports the piezoelectric film, the energy confinement layer, and the IDT electrode 54.

The energy confinement layer includes one layer or a plurality of layers, and the velocity of a bulk acoustic wave propagating through the at least one layer is higher than the velocity of an acoustic wave propagating in the vicinity of the piezoelectric film. For example, the energy confinement layer may have a multilayer structure including a low acoustic velocity layer and a high acoustic velocity layer. The low acoustic velocity layer is a film in which the acoustic velocity of a bulk wave in the low acoustic velocity layer is lower than the acoustic velocity of an acoustic wave propagating through the piezoelectric film. The high acoustic velocity layer is a film in which the acoustic velocity of a bulk wave in the high acoustic velocity layer is higher than the acoustic velocity of an acoustic wave propagating through the piezoelectric film. The support substrate may be used as the high acoustic velocity layer.

In addition, the energy confinement layer may be an acoustic impedance layer having a configuration in which a low acoustic impedance layer having a relatively low acoustic impedance and a high acoustic impedance layer having a relatively high acoustic impedance are alternately stacked.

Here, electrode parameters of the IDT electrode 54 forming the acoustic wave resonator 60 will be described.

A wavelength of the acoustic wave resonator is defined by a wavelength λ that is a repeating period in the plurality of electrode fingers 61a or 61b of the IDT electrode 54 illustrated in (b) of FIG. 2A. In addition, an electrode finger pitch is about ½ of the wavelength λ, and when a line width of the electrode fingers 61a and 61b of the comb-shaped electrodes 60a and 60b, respectively, is represented by W, and a space width between the electrode finger 61a and the electrode finger 61b adjacent to each other is represented by S, the electrode finger pitch is defined as (W+S). In addition, the duty of the IDT electrode 54 is a line width occupancy of the electrode fingers 61a and 61b, is a ratio of the line width to a value obtained by adding the line width and the space width of each of the electrode fingers 61a and 61b, and is defined by W/(W+S). In addition, an intersecting width of the IDT electrode 54 is an overlapping length of the electrode fingers when the electrode finger 61a and the electrode finger 61b are seen from the acoustic wave propagation direction (X-axis direction).

In the IDT electrode 54, when an interval between the adjacent electrode fingers is not constant, the electrode finger pitch of the IDT electrode 54 is defined as an average electrode finger pitch of the IDT electrode 54. The average electrode finger pitch of the IDT electrode 54 is defined as Di/(Ni−1), when the total number of the electrode fingers 61a and 61b in the IDT electrode 54 is represented by Ni, and when a distance between centers of the electrode finger positioned in one end and the electrode finger positioned in another end of the IDT electrode 54 in the acoustic wave propagation direction is represented by Di.

FIG. 2C is a cross-sectional view schematically illustrating a third example of an acoustic wave resonator of the acoustic wave filter 10 according to the present example embodiment. FIG. 2C illustrates a bulk acoustic wave resonator as the acoustic wave resonator of the acoustic wave filter 10. As illustrated in FIG. 2C, for example, the bulk acoustic wave resonator includes a support substrate 65, a lower electrode 66, a piezoelectric layer 67, and an upper electrode 68, stacked in this order.

The support substrate 65 supports the lower electrode 66, the piezoelectric layer 67, and the upper electrode 68, and is a silicon substrate, for example. In the support substrate 65, a cavity is provided in a region that comes into contact with the lower electrode 66. As a result, the piezoelectric layer 67 can freely vibrate.

The lower electrode 66 is provided on one surface of the support substrate 65. The upper electrode 68 is provided on one surface of the support substrate 65. As materials of the lower electrode 66 and the upper electrode 68, for example, Al including Cu in an amount of about 1% is preferably used.

The piezoelectric layer 67 is provided between the lower electrode 66 and the upper electrode 68. For example, the piezoelectric layer 67 includes at least one of zinc oxide (ZnO), aluminum nitride (AlN), lead zirconate titanate (PZT), potassium niobate (KN), lithium niobate (LN), lithium tantalate (LT), crystal, or lithium borate (LiBO) as the main component.

The bulk acoustic wave resonator having the above-described multilayer configuration induces a bulk acoustic wave inside the piezoelectric layer 67, and generates resonance by applying electric energy between the lower electrode 66 and the upper electrode 68. The bulk acoustic wave generated by the bulk acoustic wave resonator propagates between the lower electrode 66 and the upper electrode 68 in a direction perpendicular to a film surface of the piezoelectric layer 67. That is, the bulk acoustic wave resonator is a resonator using the bulk acoustic wave.

### 3. Resonance Characteristics and Bandpass Characteristics of Acoustic Wave Filter 10

First, a basic operating principle of the ladder band pass filter including one series arm resonator and one parallel arm resonator will be described.

The parallel arm resonator has a resonant frequency frp and an anti-resonant frequency fap (>frp), and the series arm resonator has a resonant frequency frs and an anti-resonant parallel frequency fas (>frs>frp). In the series arm resonator and the arm resonator having the above-described resonance characteristics, in general, the anti-resonant frequency fap of the parallel arm resonator and the resonant frequency frs of the series arm resonator are close to each other. As a result, the vicinity of the resonant frequency frp where the impedance of the parallel arm resonator approaches 0 is a lower frequency side stop band.

In addition, as the frequency increases from the lower frequency side stop band, the impedance of the parallel arm resonator in the vicinity of the anti-resonant frequency fap increases, and the impedance of the series arm resonator in the vicinity of the resonant frequency frs approaches 0. As a result, the vicinity of the anti-resonant frequency fap to the resonant frequency frs is a signal pass band in a signal path that is the series arm path. As a result, the pass band on which electrode parameters and an electromechanical coupling coefficient of the acoustic wave resonator are reflected can be formed. Further, when the frequency increases to be in the vicinity of the anti-resonant frequency fas, the impedance of the series arm resonator increases, and a higher frequency side stop band is provided.

In each of the series arm resonator and the parallel arm resonator, the impedance of the resonator is capacitive (C-characteristic) in a frequency band positioned on a lower frequency side than the resonant frequency, and the impedance of the resonator is inductive (L-characteristic) in a frequency band positioned on a higher frequency side than the resonant frequency and positioned on a lower frequency side than the anti-resonant frequency. In addition, the impedance of the resonator is capacitive in a frequency band positioned on a higher frequency side than the anti-resonant frequency.

Next, the bandpass characteristics of the acoustic wave filter 10 will be described.

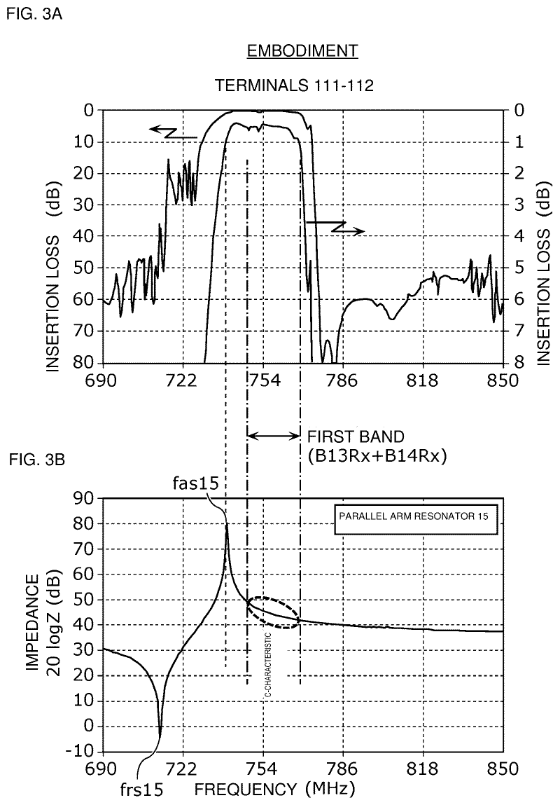

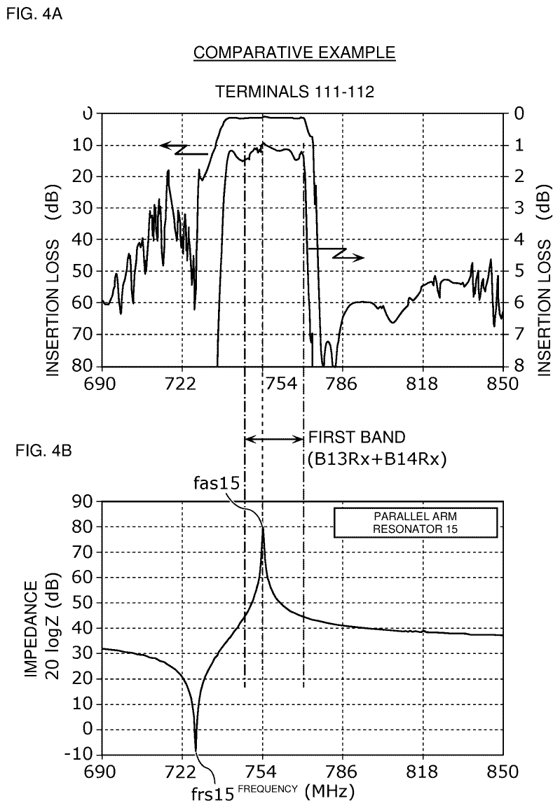

FIGS. 3A and 3B are graphs illustrating the bandpass characteristics of the acoustic wave filter 10 according to the present example embodiment, and the impedance characteristics of the parallel arm resonator 15. FIGS. 4A and 4B are graphs illustrating the bandpass characteristics of an acoustic wave filter according to Comparative Example, and the impedance characteristics of the parallel arm resonator 15.

In addition, Table 1 shows the electrode parameters of the series arm resonators and the parallel arm resonators of the acoustic wave filter according to present example embodiment and the acoustic wave filter according to Comparative Example.

TABLE 1

| | | Intersecting | | |
|---|---|---|---|---|
| Acoustic | Wavelength Å | Width | Number | |
| Wave Filter | (μm) | (μm) | of Pairs | Duty |
| Series Arm | 4.959 | 57.35 | 45 | 0.65 |
| Resonator 11 | | | | |
| Series Arm | 4.992 | 95.75 | 50 | ↑ |
| Resonator 12 | | | | |
| Series Arm | 4.992 | 115.18 | 88 | ↑ |
| Resonator 13 | | | | |
| Parallel Arm | 5.171 | 83.3 | 45 | ↑ |
| Resonator 14 | | | | |
| Parallel Arm | 5.306 (Example | 58.75 | 110 | ↑ |
| Resonator 15 | Embodiment) | | | |
| | 5.171 (Comparative | | | |
| | Example) | | | |

| | |
|---|---|
| Inductor 31 | 8nH |

When the acoustic wave filter 10 according to the present example embodiment is compared to the acoustic wave filter according to Comparative Example, the circuit configurations and the electrode parameters are the same or substantially the same, except that the wavelength A of the IDT electrode of the parallel arm resonator 15 is different.

In the acoustic wave filter according to Comparative Example, as illustrated in FIG. 4B, an anti-resonant frequency fas15 of the parallel arm resonator 15 is positioned in the frequency range of the first band. Although not illustrated in the drawing, the resonant frequency of the series arm resonators 11 to 13 and the anti-resonant frequency of the parallel arm resonator 14 are positioned in the frequency range of the first band.

As a result, as illustrated in FIG. 4A, the acoustic wave filter according to Comparative Example defines a band pass filter that includes a pass band including the first band. The insertion loss in the first band is, for example, more than about 1 dB. In the acoustic wave filter according to Comparative Example, the impedance in the pass band of the parallel arm resonators 14 and 15 is very high. Therefore, the impedance in the pass band of the acoustic wave filter is higher than a reference impedance, and the insertion loss increases due to matching loss.

On the other hand, in the acoustic wave filter 10 according to the present example embodiment, as illustrated in FIG. 3B, the anti-resonant frequency fas15 of the parallel arm resonator 15 is positioned on a lower frequency side than the first band. Although not illustrated in FIG. 3B, the resonant frequency of the series arm resonators 11 to 13 and the anti-resonant frequency of the parallel arm resonator 14 are positioned in the frequency range of the first band.

All of the anti-resonant frequencies of the plurality of parallel arm resonators (in the present example embodiment, only the parallel arm resonator 14) excluding the parallel arm resonator 15 and the resonant frequencies of the one or more series arm resonators (in the present example embodiment, the series arm resonators 11 to 13) do not need to be positioned in the frequency range of the first band. The plurality of parallel arm resonators excluding the parallel arm resonator 15 and the one or more series arm resonators may be resonators contributing to the formation of the pass band of the acoustic wave filter 10. Specifically, at least a portion of a resonance band that is a frequency range from the resonant frequency to the anti-resonant frequency may overlap the first band.

As a result, as illustrated in FIG. 3A, the acoustic wave filter 10 according to the present example embodiment defines a band pass filter that includes a pass band including the first band. In addition, the insertion loss in the first band is, for example, about 1 dB or less. In the acoustic wave filter 10 according to the example embodiment, the impedance in the pass band of the parallel arm resonator 15 is capacitive (in FIG. 3B, C-characteristic). Therefore, the impedance in the pass band of the acoustic wave filter 10 can be reduced. Therefore, compared to the acoustic wave filter according to Comparative Example, the impedance in the pass band can be approximated to the reference impedance, and the insertion loss caused by matching loss can be reduced.

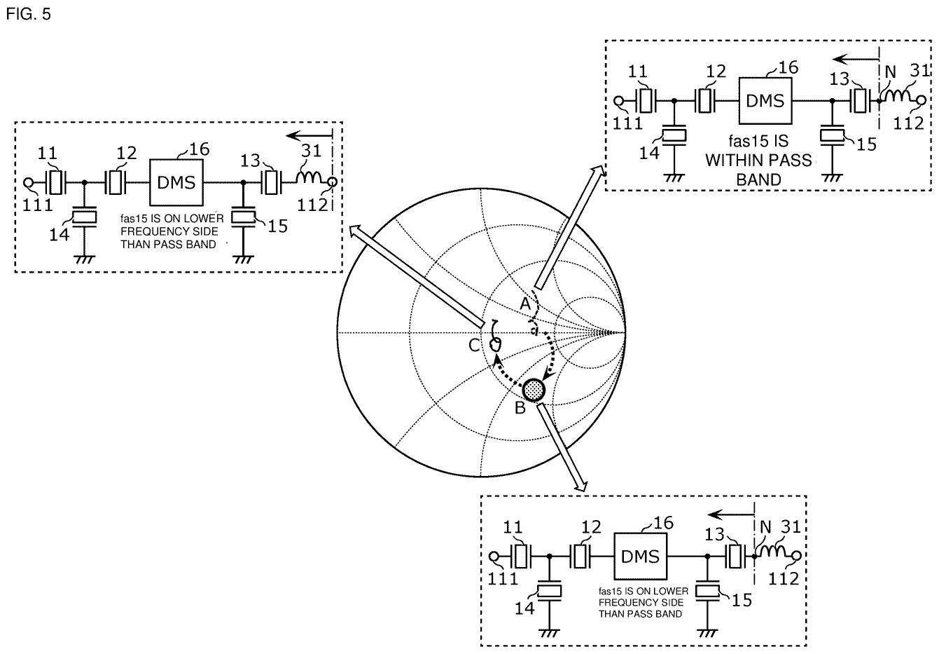

Here, the configuration where the acoustic wave filter 10 according to the present example embodiment can reduce the impedance in the pass band will be described in detail using FIG. 5.

FIG. 5 is a Smith chart illustrating the impedance of the pass band of the acoustic wave filter 10 according to the present example embodiment. In the Smith chart of the drawing, a state A, a state B, and a state C of the impedance of the pass band are illustrated.

First, the state A represents the impedance of the pass band when the series arm resonator 13 side is seen from a connection node N between the inductor 31 and the series arm resonator 13 in the acoustic wave filter according to Comparative Example. Since the anti-resonant frequency fas15 of the parallel arm resonator 15 is positioned in the first band, the impedance of the pass band is higher than the reference impedance and positioned in an inductive region.

Next, the state B represents the impedance of the pass band when the series arm resonator 13 side is seen from the connection node N in the acoustic wave filter 10 according to the present example embodiment. The anti-resonant frequency fas15 of the parallel arm resonator 15 is positioned on a lower frequency side than the first band such that a capacitive region of the parallel arm resonator 15 overlaps the pass band of the acoustic wave filter 10. As a result, the impedance of the pass band of the acoustic wave filter 10 is positioned in the capacitive region in a state where the capacitive element (the capacitance component of the parallel arm resonator 15) is connected in parallel and a constant conductance circle is shifted clockwise with respect to the state A.

Next, the state C represents the impedance of the pass band when the acoustic wave filter 10 is seen from the input and output terminal 112 in the acoustic wave filter 10 according to the present example embodiment. The impedance of the pass band of the acoustic wave filter 10 approaches the reference impedance in a state where the inductor 31 is connected in series and a constant resistance circle is shifted clockwise with respect to the state B.

In the general ladder acoustic wave filter, the impedance in the anti-resonant frequency of the acoustic wave resonator is very high, and thus the impedance in the pass band of the parallel arm resonator is very high. In addition, when the size of the acoustic wave filter is reduced, the capacitance of the acoustic wave resonator decreases, and the impedance of the acoustic wave resonator increases.

On the other hand, in the acoustic wave filter 10 according to the present example embodiment, by positioning the anti-resonant frequency fas15 of the parallel arm resonator 15 connected closest to the inductor 31 among the plurality of parallel arm resonators on a lower frequency side than the first band, the impedance in the first band of the parallel arm resonator 15 can be made capacitive. That is, by positioning the anti-resonant frequency fas15 and the resonant frequency frs15 of the parallel arm resonator 15 connected closest to the inductor 31 among the plurality of parallel arm resonators outside the frequency range of the first band, the impedance in the first band of the parallel arm resonator 15 can be made capacitive. With this configuration, the impedance in the first band of the acoustic wave filter 10 can be shifted to a lower impedance by a parallel capacitance component of the parallel arm resonator 15 and a series inductance component of the inductor 31 and can approach the reference impedance. Accordingly, the matching loss can be reduced, and the acoustic wave filter 10 that is reduced in loss and size can be provided.

Next, in the acoustic wave filter 10 according to the present example embodiment, the positioning of the anti-resonant frequency fas15 of the parallel arm resonator 15 on a lower frequency side than the first band will be expressed using the electrode finger pitch (half of the wavelength λ).

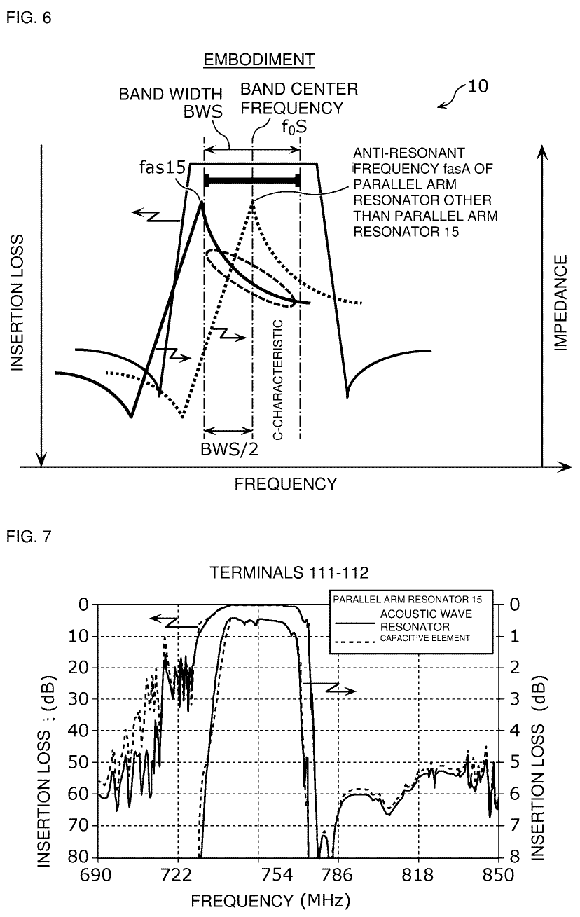

FIG. 6 is a diagram illustrating a relationship between the first band of the acoustic wave filter 10 according to the present example embodiment and the anti-resonant frequency of the parallel arm resonator. Here, a frequency range of the first band is represented by BWS, a center frequency of the first band is represented by f₀S, an average value of electrode finger pitches of the IDT electrodes of the plurality of parallel arm resonators (in the present example embodiment, only the parallel arm resonator 14) excluding the parallel arm resonator 15 is represented by P_{PA}, an electrode finger pitch of the IDT electrode of the parallel arm resonator 15 is represented by P1. As illustrated in FIG. 6, an average value fasA of the anti-resonant frequencies of the plurality of parallel arm resonators (in the present example embodiment, only the parallel arm resonator 14) excluding the parallel arm resonator 15 substantially matches with the center frequency f₀S. As a result, the positioning of the anti-resonant frequency fas15 of the parallel arm resonator 15 on a lower frequency side than the first band is equivalent to the shifting of the anti-resonant frequency fas15 to a lower frequency side than the average value fasA by BWS/2 or more. When this configuration is expressed by the electrode finger pitches of the parallel arm resonators, Expression 1 is satisfied.

$$P 1 \geq {P}_{PA} \times \{ 1 + ( BWS / {f}_{0} S ) / 2 \} \qquad ( Expression 1 )$$

Expression 1 represents that the electrode finger pitch P1 of the parallel arm resonator 15 is more than the average value P_{PA} of the electrode finger pitches of the IDT electrodes of the plurality of parallel arm resonators excluding the parallel arm resonator 15 by at least the electrode finger pitch corresponding to half (BWS/f₀S)/2 of the frictional band width of the first band.

For example, a case where the first band is a combined band of a downlink operating band (about 746 MHz to about 756 MHZ) of a band B13 for LTE and a downlink operating band (about 758 MHZ to about 768 MHz) of a band B14 for LTE will be described. In this case, BWS=about 22 MHZ (=about 768 MHz-about 746 MHZ), and f₀S=about 757 MHz. In addition, in Table 1, P_{PA} of the acoustic wave filter 10=about 2.5855 μm (=about 5.171 μm/2: the electrode finger pitch of the parallel arm resonator 14).

When BWS, f₀S, and P_{PA} described above are substituted into Expression 1, the right side of Expression 1: P_{PA}×{1+ (BWS/f₀S)/2}=about 2.623 μm. On the other hand, it can be understood from Table 1 that P1 of the acoustic wave filter 10 is about 2.653 μm and the relationship of Expression 1 is satisfied.

With this configuration, by setting the electrode finger pitch P1 of the parallel arm resonator 15 to be more than the average value P_{PA} of the electrode finger pitches of the plurality of parallel arm resonators excluding the parallel arm resonator 15 by the electrode finger pitch (=P_{PA} (BWS/f₀S)/2) corresponding to half of the frequency range BWS of the first band, the anti-resonant frequency fas15 of the parallel arm resonator 15 can be positioned on a lower frequency side than the first band. As a result, the impedance in the first band of the acoustic wave filter 10 can be shifted to a lower impedance by a parallel capacitance component of the parallel arm resonator 15 and a series inductance component of the inductor 31 and can approach the reference impedance. Accordingly, the matching loss can be reduced, and the acoustic wave filter 10 that is reduced in loss and size can be provided.

In addition, when an average value of electrode finger pitches of the IDT electrodes of the plurality of parallel arm resonators (in the present example embodiment, only the parallel arm resonator 14) excluding the parallel arm resonator 15 and the one or more series arm resonators (in the present example embodiment, the series arm resonators 11 to 13) is represented by P_{A}, Expression 2 may be satisfied.

$$( {P}_{SA} - {P}_{PA} ) / {P}_{A} > BWS / {f}_{0} S \qquad ( Expression 2 )$$

When the capacitive region of the parallel arm resonator 15 is positioned in the first band, the capacitance component of the pass band of the acoustic wave filter 10 increases, and the pass band of the acoustic wave filter 10 tends to become narrower. On the other hand, Expression 2 represents that a difference between the resonant frequencies of the plurality of parallel arm resonators excluding the parallel arm resonator 15 and the resonant frequencies of the one or more series arm resonators is more than the frequency range BWS of the first band. As a result, even when the pass band of the acoustic wave filter 10 is narrower than the capacitance component of the parallel arm resonator 15, low loss can be achieved while ensuring the first band in the pass band.

Next, a case where a first parallel arm resonator (parallel arm resonator 15) is an acoustic wave resonator and a case where the first parallel arm resonator is a capacitive element are compared. FIG. 7 is a graph illustrating bandpass characteristics of the acoustic wave filter 10 according to the example embodiment when the parallel arm resonator 15 of the acoustic wave filter 10 is an acoustic wave resonator and when the parallel arm resonator 15 is a capacitive element.

As illustrated in FIG. 7, when the parallel arm resonator 15 is an acoustic wave resonator, the attenuation of an attenuation band on a lower frequency side than the pass band is more than that when the parallel arm resonator 15 is a capacitive element. The reason for this is that the resonant frequency frs15 of the parallel arm resonator 15 overlaps the above-described attenuation band. That is, the parallel arm resonator 15 is an acoustic wave resonator having impedance characteristics with strong frequency dependence such that attenuation characteristics of the acoustic wave filter 10 can be improved.

### 4. Resonance Characteristics and Bandpass

Characteristics of Acoustic Wave Filter 10A according to a Modified Example

The acoustic wave filter 10 according to the present example embodiment is reduced in loss and size by causing the capacitive region positioned on a higher frequency side than the anti-resonant frequency fas15 of the parallel arm resonator 15 to overlap the first band. On the other hand, in an acoustic wave filter 10A according to a modified example, a reduction in loss and size is achieved by causing the capacitive region positioned on a lower frequency side than the resonant frequency frs15 of the parallel arm resonator 15 to overlap the first band.

The acoustic wave filter 10A according to the present modified example includes input and output terminals 111 and 112, series arm resonators 11, 12, and 13, parallel arm resonators 14 and 15, a longitudinally coupled resonator 16, and an inductor 31. That is, the circuit configuration of the acoustic wave filter 10A according to the modified example is the same or substantially the same as the circuit configuration of the acoustic wave filter 10 according to the above-described example embodiment. When the acoustic wave filter 10A according to the present modified example is compared to the acoustic wave filter 10 according to the above-described example embodiment, the positions of the resonant frequency and the anti-resonant frequency of the parallel arm resonator 15 are different.

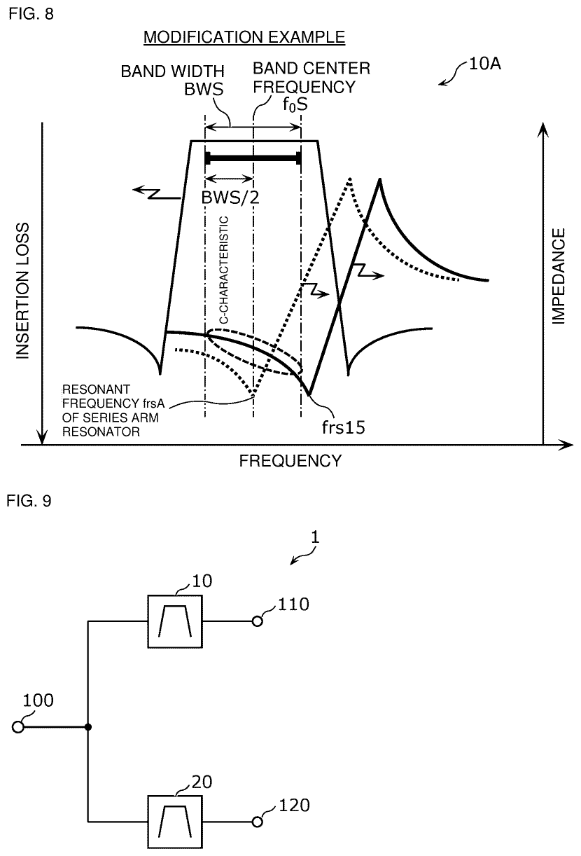

FIG. 8 is a diagram illustrating a relationship between the first band of the acoustic wave filter 10A according to the modified example of the example embodiment and the resonant frequencies of the parallel arm resonator 15 and the series arm resonators 11 to 13. As illustrated in FIG. 8, in the acoustic wave filter 10A according to the modified example, the resonant frequency frs15 of the parallel arm resonator 15 is positioned on a higher frequency side than the first band. The resonant frequencies of the series arm resonators 11 to 13 and the anti-resonant frequency of the parallel arm resonator 14 are positioned in the frequency range of the first band.

All of the anti-resonant frequencies of the plurality of parallel arm resonators (in the above-described example embodiment, only the parallel arm resonator 14) excluding the parallel arm resonator 15 and the resonant frequencies of the one or more series arm resonators (in the above-described example embodiment, the series arm resonators 11 to 13) do not need to be positioned in the frequency range of the first band. The plurality of parallel arm resonators excluding the parallel arm resonator 15 and the one or more series arm resonators may be resonators contributing to the pass band of the acoustic wave filter 10A. Specifically, at least a portion of a resonance band that is a frequency range from the resonant frequency to the anti-resonant frequency may overlap the first band.

As a result, the acoustic wave filter 10A according to the modified example defines a band pass filter that includes a pass band including the first band. In the acoustic wave filter 10A, the impedance in the pass band of the parallel arm resonator 15 is capacitive (in FIG. 8, C-characteristic). Therefore, the impedance in the pass band of the acoustic wave filter 10A can be reduced. Therefore, compared to the acoustic wave filter according to Comparative Example, the impedance in the pass band can be approximated to the reference impedance, and the insertion loss caused by matching loss can be reduced.

The impedance of the pass band of the acoustic wave filter 10A according to the modified example transitions in the same or substantially the same manner that of the state A, the state B, and the state C of the impedance illustrated in FIG. 5.

In the acoustic wave filter 10A according to the present modified example, by positioning the resonant frequency frs15 of the parallel arm resonator 15 connected closest to the inductor 31 among the plurality of parallel arm resonators on a higher frequency side than the first band, the impedance in the first band of the parallel arm resonator 15 can be made capacitive. That is, by positioning the anti-resonant frequency fas15 and the resonant frequency frs15 of the parallel arm resonator 15 connected closest to the inductor 31 among the plurality of parallel arm resonators outside the frequency range of the first band, the impedance in the first band of the parallel arm resonator 15 can be made capacitive. With this configuration, the impedance in the first band of the acoustic wave filter 10A can be shifted to a lower impedance by a parallel capacitance component of the parallel arm resonator 15 and a series inductance component of the inductor 31 and can approach the reference impedance. Accordingly, the matching loss can be reduced, and the acoustic wave filter 10A that is reduced in loss and size can be provided.

Next, in the acoustic wave filter 10A according to the modified example, the positioning of the resonant frequency frs15 of the parallel arm resonator 15 on a higher frequency side than the first band will be expressed using the electrode finger pitch (half of the wavelength λ).

A frequency range of the first band is represented by BWS, a center frequency of the first band is represented by f₀S, an average value of electrode finger pitches of the IDT electrodes of the plurality of series arm resonators (in the present example embodiment, the series arm resonators 11 to 13) is represented by P_{SA}, and an electrode finger pitch of the IDT electrode of the parallel arm resonator 15 is represented by P1. As illustrated in FIG. 8, an average value frsA of the resonant frequencies of the plurality of series arm resonators (in the present example embodiment, only the series arm resonators 11 to 13) substantially matches with the center frequency f₀S. As a result, the positioning of the resonant frequency frs15 of the parallel arm resonator 15 on a higher frequency side than the first band is equivalent to the shifting of the resonant frequency frs15 to a higher frequency side than the average value frsA by BWS/2 or more. When this configuration is expressed by the electrode finger pitches of the parallel arm resonator 15 and the series arm resonators 11 to 13, Expression 3 is satisfied.

$$P 1 \leq {P}_{SA} \times \{ 1 - ( BWS / {f}_{0} S ) / 2 \} \qquad ( Expression 3 )$$

Expression 3 represents that the electrode finger pitch P1 of the parallel arm resonator 15 is less than the average value P_{SA} of the electrode finger pitches of the IDT electrodes of the plurality of series arm resonators by at least the electrode finger pitch corresponding to half (BWS/f₀S)/2 of the frictional band width of the first band.

For example, a case where the first band is a combined band of a downlink operating band (about 746 MHz to about 756 MHZ) of a band B13 for LTE and a downlink operating band (about 758 MHZ to about 768 MHz) of a band B14 for LTE will be described. In this case, BWS=about 22 MHz, and f₀S=about 757 MHz. In addition, in Table 1, P_{SA} of the acoustic wave filter 10=about 2.4905 μm (=about 4.981 μm/2: the average electrode finger pitch of the series arm resonators 11 to 13).

When BWS, f₀S, and P_{SA} described above are substituted into Expression 3, the right side of Expression 3: P_{SA}×{1−(BWS/f₀S)/2}=about 2.454 μm. That is, for example, P1≤about 2.454 μm is a condition.

With this configuration, by setting the electrode finger pitch P1 of the parallel arm resonator 15 to be less than the average value P_{SA} of the electrode finger pitches of the series arm resonators by the electrode finger pitch (=P_{SA} (BWS/f₀S)/2) corresponding to half of the frequency range BWS of the first band, the resonant frequency frs15 of the parallel arm resonator 15 can be positioned on a higher frequency side than the first band. As a result, the impedance in the first band of the acoustic wave filter 10A can be shifted to a lower impedance by a parallel capacitance component of the parallel arm resonator 15 and a series inductance component of the inductor 31 and can approach the reference impedance. Accordingly, the matching loss can be reduced, and the acoustic wave filter 10A that is reduced in loss and size can be provided.

### 5. Circuit Configuration of Multiplexer

Next, a multiplexer 1 including an acoustic wave filter 10 according to an example embodiment will be described. FIG. 9 is a circuit configuration diagram illustrating the multiplexer 1 according to the present example embodiment. As illustrated in FIG. 9, the multiplexer 1 includes the acoustic wave filter 10, a filter 20, a common terminal 100, and input and output terminals 110 and 120.

The common terminal 100 is connected to, for example, an antenna.

The acoustic wave filter 10 is an acoustic wave filter 10 according to an example embodiment and includes the pass band including the first band. One end of the acoustic wave filter 10 is connected to the common terminal 100, and another end of the acoustic wave filter 10 is connected to the input and output terminal 110.

The filter 20 includes a pass band including a second band. One end of the filter 20 is connected to the common terminal 100, and another end of the filter 20 is connected to the input and output terminal 120. That is, the acoustic wave filter 10 and the filter 20 are connected in common. The structure of the filter 20 is not particularly limited and may be, for example, an acoustic wave filter or an LC filter including an inductor and a capacitor.

According to the above-described configuration, the acoustic wave filter 10 that is reduced in loss and size is provided, and a reduction in loss and size can be realized as the multiplexer 1.

It is preferable that the pass band of the filter 20 is positioned on a lower frequency side than the pass band of the acoustic wave filter 10. With this configuration, the resonant frequency frs15 of the parallel arm resonator 15 of the acoustic wave filter 10 can overlap the pass band of the filter 20, and thus the insertion loss of the pass band of the filter 20 can be reduced.

In addition, in the multiplexer 1, the acoustic wave filter 10A according to the above-described modified example may be provided instead of the acoustic wave filter 10. In this case, it is preferable that the pass band of the filter 20 is positioned on a higher frequency side than the pass band of the acoustic wave filter 10A. With this configuration, the anti-resonant frequency fas15 of the parallel arm resonator 15 of the acoustic wave filter 10A can overlap the pass band of the filter 20, and thus the insertion loss of the pass band of the filter 20 can be reduced.

In the multiplexer 1 according to the present example embodiment, a filter other than the acoustic wave filter 10 and the filter 20 may be connected to the common terminal 100. In addition, an impedance matching circuit including at least one of an inductor and a capacitor may be connected to at least one of a path connecting the common terminal 100 and the input and output terminal 110 and a path connecting the common terminal 100 and the input and output terminal 120. In addition, the multiplexer 1 does not need to include the common terminal 100 and the input and output terminals 110 and 120.

### 6 Effects or the Like

As described above, the acoustic wave filter 10 according to the above-described example embodiment includes the pass band including the first band, and includes the input and output terminals 111 and 112, one or more series arm resonators in a series arm path connecting the input and output terminals 111 and 112, a plurality of parallel arm resonators connected between the series arm path and a ground, and the inductor 31 connected to the input and output terminal 112 and disposed in series in the series arm path, in which the resonant frequency frs15 and the anti-resonant frequency fas15 of the parallel arm resonator 15 connected closest to the inductor 31 among the plurality of parallel arm resonators are positioned outside a frequency range of the first band.

With this configuration, by positioning the anti-resonant frequency fas15 and the resonant frequency frs15 of the parallel arm resonator 15 outside the frequency range of the first band, the impedance in the first band of the parallel arm resonator 15 can be made capacitive. As a result, the impedance in the first band of the acoustic wave filter 10 can be shifted to a lower impedance by a parallel capacitance component of the parallel arm resonator 15 and a series inductance component of the inductor 31 and can approach the reference impedance. Accordingly, the acoustic wave filter 10 that is reduced in loss and size can be provided.

In addition, for example, in the acoustic wave filter 10, the anti-resonant frequency fas15 of the parallel arm resonator 15 is positioned on a lower frequency side than the first band.

With this configuration, by positioning the anti-resonant frequency fas15 of the parallel arm resonator 15 on a lower frequency side than the first band, the impedance in the first band of the parallel arm resonator 15 can be made capacitive.

In addition, for example, in the acoustic wave filter 10A according to the above-described modified example, the resonant frequency frs15 of the parallel arm resonator 15 is positioned on a higher frequency side than the first band.

With this configuration, by positioning the resonant frequency frs15 of the parallel arm resonator 15 on a higher frequency side than the first band, the impedance in the first band of the parallel arm resonator 15 can be made capacitive.

In addition, for example, in the acoustic wave filters 10 and 10A, an anti-resonant frequency of each of the plurality of parallel arm resonators excluding the parallel arm resonator 15 is positioned in the frequency range of the first band.

With this configuration, the acoustic wave filters 10 and 10A define a ladder band pass filter that includes a pass band including the first band.

In addition, in the acoustic wave filter 10 according to the above-described example embodiment, each of the plurality of parallel arm resonators includes an IDT electrode, and when a frequency range of the first band is represented by BWS, a center frequency of the first band is represented by f₀S, an electrode finger pitch of the IDT electrode of the parallel arm resonator 15 is represented by P1, and an average value of electrode finger pitches of the IDT electrodes of the plurality of parallel arm resonators excluding the parallel arm resonator 15 is represented by P_{PA}, P1≥P_{PA}×{1+ (BWS/f₀S)/2} is satisfied.

With this configuration, by setting the electrode finger pitch P1 of the parallel arm resonator 15 to be more than the average value P_{PA} of the electrode finger pitches of the plurality of parallel arm resonators excluding the parallel arm resonator 15 by the electrode finger pitch corresponding to half of the frequency range BWS of the first band, the anti-resonant frequency fas15 of the parallel arm resonator 15 can be positioned on a lower frequency side than the first band. As a result, the impedance in the first band of the acoustic wave filter 10 can be shifted to a lower impedance by a parallel capacitance component of the parallel arm resonator 15 and a series inductance component of the inductor 31 and can approach the reference impedance. Accordingly, the acoustic wave filter 10 that is reduced in loss and size can be provided.

In addition, in the acoustic wave filter 10A according to the above-described modified example of the example embodiment, each of the one or more series arm resonators and the plurality of parallel arm resonators includes an IDT electrode, and when a frequency range of the first band is represented by BWS, a center frequency of the first band is represented by f₀S, an electrode finger pitch of the IDT electrode of the parallel arm resonator 15 is represented by P1, and an average value of electrode finger pitches of the IDT electrodes of the one or more series arm resonators is represented by P_{SA}, P1≤P_{SA}×{1−(BWS/f₀S)/2} is satisfied.

With this configuration, by setting the electrode finger pitch P1 of the parallel arm resonator 15 to be less than the average value P_{SA} of the electrode finger pitches of the series arm resonators by the electrode finger pitch corresponding to half of the frequency range BWS of the first band, the resonant frequency frs15 of the parallel arm resonator 15 can be positioned on a higher frequency side than the first band. As a result, the impedance in the first band of the acoustic wave filter 10A can be shifted to a lower impedance by a parallel capacitance component of the parallel arm resonator 15 and a series inductance component of the inductor 31 and can approach the reference impedance. Accordingly, the acoustic wave filter 10A that is reduced in loss and size can be provided.

In addition, for example, in the acoustic wave filters 10 and 10A, when an average value of electrode finger pitches of the IDT electrodes of the plurality of parallel arm resonators excluding the parallel arm resonator 15 is represented by P_{PA}, an average value of electrode finger pitches of the IDT electrodes of the one or more series arm resonators is represented by P_{SA}, and an average value of electrode finger pitches of the IDT electrodes of the plurality of parallel arm resonators excluding the parallel arm resonator 15 and the one or more series arm resonators is represented by P_{A}, (P_{SA}−P_{PA})/P_{A}>BWS/f₀S is satisfied.

When the capacitive region of the parallel arm resonator 15 is positioned in the first band, the capacitance component of the pass band of the acoustic wave filter 10 increases, and the pass band of the acoustic wave filter 10 tends to become narrower. With this configuration, even when the pass band of the acoustic wave filter 10 is narrower than the capacitance component of the parallel arm resonator 15, low loss can be realized while ensuring the first band in the pass band.

In addition, for example, the acoustic wave filters 10 and 10A may further include the longitudinally coupled resonator 16 connected between the input and output terminal 111 and the inductor 31.

With this configuration, at least either bandpass characteristics or attenuation characteristics can be improved.

In addition, for example, in the acoustic wave filters 10 and 10A, the first band includes a plurality of bands standardized by 3GPP (registered trademark).

With this configuration, the acoustic wave filters 10 and 10A can include a filter that includes a pass band including a plurality of bands where frequencies are close to each other.

In addition, for example, in the acoustic wave filters 10 and 10A, the first band includes a downlink operating band of a band B13 for LTE or a band n13 for 5G-NR and a downlink operating band of a band B14 for LTE or a band n14 for 5G-NR.

With this configuration, the acoustic wave filters 10 and 10A can include a band filter that includes a pass band including the B13 downlink operating band and the B14 downlink operating band where frequencies are close to each other.

### OTHER EXAMPLE EMBODIMENTS

Although the acoustic wave filters according to example embodiments of the present invention have been described above by using example embodiments and modified examples, the present invention is not limited to the above-described example embodiments and modified examples. The present invention also includes modified examples obtained by applying various modifications conceivable by those skilled in the art to the above-described example embodiments within a scope not departing from the present invention, and various types of equipment in which acoustic wave filters according to example embodiments of the present invention can be incorporated.

In addition, for example, in acoustic wave filters according to example embodiments and modified examples, a matching element such as, for example, an inductor or a capacitor, and a switch circuit may be connected between respective components.

For example, the resonant frequency and the anti-resonant frequency described above in the example embodiments and the modified examples are derived by bringing an RF probe into contact with two input and output electrodes of the acoustic wave resonator to measure reflection characteristics.

Example embodiments of the present invention can be widely used for communication equipment such as, for example, a mobile phone, as an acoustic wave filter having low loss, which is applicable to a multi-band frequency standard.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter that includes a pass band including a first band, the acoustic wave filter comprising:
a first input and output terminal and a second input and output terminal;
one or more series arm resonators in a series arm path connecting the first input and output terminal and the second input and output terminal;
a plurality of parallel arm resonators connected between the series arm path and a ground; and
an inductor connected to the first input and output terminal and provided in series in the series arm path; wherein
a resonant frequency and an anti-resonant frequency of a first parallel arm resonator connected closest to the inductor of the plurality of parallel arm resonators are outside a frequency range of the first band.

2. The acoustic wave filter according to claim 1, wherein the anti-resonant frequency of the first parallel arm resonator is on a lower frequency side than the first band.

3. The acoustic wave filter according to claim 1, wherein the resonant frequency of the first parallel arm resonator is on a higher frequency side than the first band.

4. The acoustic wave filter according to claim 2, wherein an anti-resonant frequency of each of the plurality of parallel arm resonators excluding the first parallel arm resonator is in the frequency range of the first band.

5. The acoustic wave filter according to claim 1, further comprising a longitudinally coupled resonator connected between the second input and output terminal and the inductor.

6. The acoustic wave filter according to claim 1, wherein the first band includes a plurality of bands standardized by 3GPP (registered trademark).

7. The acoustic wave filter according to claim 6, wherein the first band includes a downlink operating band of a band B13 for LTE or a band n13 for 5G-NR and a downlink operating band of a band B14 for LTE or a band n14 for 5G-NR.

8. An acoustic wave filter that includes a pass band including a first band, the acoustic wave filter comprising:
a first input and output terminal and a second input and output terminal;
one or more series arm resonators in a series arm path connecting the first input and output terminal and the second input and output terminal;
a plurality of parallel arm resonators connected between the series arm path and a ground; and
an inductor in series between the first input and output terminal and the one or more series arm resonators; wherein
each of the plurality of parallel arm resonators includes an interdigital transducer (IDT) electrode; and
when a frequency range of the first band is represented by BWS, a center frequency of the first band is represented by f₀S, an electrode finger pitch of the IDT electrode of a first parallel arm resonator connected closest to the inductor among the plurality of parallel arm resonators is represented by P1, and an average value of electrode finger pitches of the IDT electrodes of the plurality of parallel arm resonators excluding the first parallel arm resonator is represented by P_{PA}, P1≥ P_{PA}×{1+ (BWS/f₀S)/2} is satisfied.

9. The acoustic wave filter according to claim 5, wherein when a frequency range of the first band is represented by BWS, a center frequency of the first band is represented by f₀S, an average value of electrode finger pitches of the IDT electrodes of the plurality of parallel arm resonators excluding the first parallel arm resonator is represented by P_{PA}, an average value of electrode finger pitches of the IDT electrodes of the one or more series arm resonators is represented by P_{SA}, and an average value of electrode finger pitches of the IDT electrodes of the plurality of parallel arm resonators excluding the first parallel arm resonator and the one or more series arm resonators is represented by P_{A}, (P_{SA}−P_{PA})/P_{A}>BWS/f₀S is satisfied.

10. The acoustic wave filter according to claim 9, wherein when a frequency range of the first band is represented by BWS, a center frequency of the first band is represented by f₀S, an average value of electrode finger pitches of the IDT electrodes of the plurality of parallel arm resonators excluding the first parallel arm resonator is represented by P_{PA}, an average value of electrode finger pitches of the IDT electrodes of the one or more series arm resonators is represented by P_{SA}, and an average value of electrode finger pitches of the IDT electrodes of the plurality of parallel arm resonators excluding the first parallel arm resonator and the one or more series arm resonators is represented by P_{A}, (P_{SA}−P_{PA})/P_{A}>BWS/f₀S is satisfied.

11. The acoustic wave filter according to claim 9, further comprising a longitudinally coupled resonator connected between the second input and output terminal and the inductor.

12. The acoustic wave filter according to claim 9, wherein the first band includes a plurality of bands standardized by 3GPP (registered trademark).

13. The acoustic wave filter according to claim 12, wherein the first band includes a downlink operating band of a band B13 for LTE or a band n13 for 5G-NR and a downlink operating band of a band B14 for LTE or a band n14 for 5G-NR.

14. An acoustic wave filter that includes a pass band including a first band, the acoustic wave filter comprising:
a first input and output terminal and a second input and output terminal;
one or more series arm resonators in a series arm path connecting the first input and output terminal and the second input and output terminal;
a plurality of parallel arm resonators connected between the series arm path and a ground; and
an inductor in series between the first input and output terminal and the one or more series arm resonators; wherein
each of the one or more series arm resonators and the plurality of parallel arm resonators includes an IDT electrode; and
when a frequency range of the first band is represented by BWS, a center frequency of the first band is represented by f₀S, an electrode finger pitch of the IDT electrode of a first parallel arm resonator connected closest to the inductor among the plurality of parallel arm resonators is represented by P1, and an average value of electrode finger pitches of the IDT electrodes of the one or more series arm resonators is represented by P_{SA}, P1≤ P_{SA}×{1−(BWS/f₀S)/2} is satisfied.

15. The acoustic wave filter according to claim 14, wherein when a frequency range of the first band is represented by BWS, a center frequency of the first band is represented by f₀S, an average value of electrode finger pitches of the IDT electrodes of the plurality of parallel arm resonators excluding the first parallel arm resonator is represented by P_{PA}, an average value of electrode finger pitches of the IDT electrodes of the one or more series arm resonators is represented by P_{SA}, and an average value of electrode finger pitches of the IDT electrodes of the plurality of parallel arm resonators excluding the first parallel arm resonator and the one or more series arm resonators is represented by P_{A}, (P_{SA}−P_{PA})/P_{A}>BWS/f₀S is satisfied.

16. The acoustic wave filter according to claim 14, further comprising a longitudinally coupled resonator connected between the second input and output terminal and the inductor.

17. The acoustic wave filter according to claim 14, wherein the first band includes a plurality of bands standardized by 3GPP (registered trademark).

18. The acoustic wave filter according to claim 17, wherein the first band includes a downlink operating band of a band B13 for LTE or a band n13 for 5G-NR and a downlink operating band of a band B14 for LTE or a band n14 for 5G-NR.
